(19) United States
(12) Patent Application Publication
(10) Pub. No.: US 2010/0012182 A1
(43) Pub. Date: Jan. 21, 2010

(54) Dye sensitized solar cell and method of fabricating the same

(75) Inventor: Hirotaka Mori, Kanagawa (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/458,497

(22) Filed: Jul. 14, 2009

(30) Foreign Application Priority Data
Jul. 16, 2008 (JP) 2008-184978

(51) Int. Cl. H01L 31/0224; H01L 31/18

(52) U.S. Cl. 136/256; 438/73; 257/E21.158; 257/E31.124

(57) ABSTRACT

A method for easily forming a dye-sensitized solar cell having a thick porous layer without increasing a thickness of a collector electrode. The dye-sensitized solar cell includes a light transmissive substrate and a plurality of recesses formed on the light transmissive substrate. Each recess has an opening partitioned by a partition wall. The solar cell also includes a collector electrode that covers the partition wall. The collector electrode has an end face on a bottom surface of the recess. The solar cell also includes a porous layer that covers the light transmissive substrate within each recess and the collector electrode. At least one kind of sensitizing dye is absorbed in the porous layer.

### BACKGROUND OF THE INVENTION

1. Field of the Invention

The present invention relates to a dye-sensitized solar cell that converts solar energy into electrical energy by means of dye, and a method of fabricating the dye-sensitized solar cell.

2. Description of the Related Art

It is thought that an amount of solar energy received by the Earth is one hundred thousand times larger than all the electricity consumed in the world.

A solar cell is a device for converting this resource (sunlight) into electrical energy. Electrical energy is an easy source to use for us human race. The solar cell has a history of about fifty years.

It is said that renewable energy, including a solar energy, has little impact on the environment and is therefore ideal energy resources. However, renewable energy has not yet become very popular. The major reason is its high power costs.

Under these circumstances, reduction in power costs is necessary to vitalize the market and realize an energy supply system (or a society) that is in harmony with nature. To this end, improvement in efficiency and reduction in material cost and fabrication costs are necessary for solar cells.

A dye-sensitized solar cell is expected to become a technology that will solve these problems.

A conventional dye-sensitized solar cell includes a glass substrate, plurality of strip-shaped collector electrodes formed on the glass substrate, and a porous layer (anode electrode) formed on the glass substrate in a manner to directly cover the collector electrodes. The porous layer is made from titanium oxide that has absorbed a sensitizing dye such as a ruthenium metal complex. The conventional dye-sensitized solar cell also includes a metal plate (cathode electrode) covered with platinum. The metal plate faces the porous layer with an electrolyte being provided between the metal plate and the porous layer. The conventional dye-sensitized solar cell also includes a frame (housing) that confines the electrolyte. This solar cell is fabricated by the following steps: forming a tungsten film on the glass substrate by CVD; etching the tungsten film by photolitho etching to form the strip-shaped collector electrodes; applying onto the glass substrate a dispersion liquid that contains fine particles of titanium oxide having a diameter of between about 20 nm and 30 nm; performing sintering processing at about 450° C. for about two hours to form a porous layer comprised of titanium oxide that covers the collector electrodes; immersing the formed porous layer in an alcohol solution containing the ruthenium metal complex to make the porous layer absorb the ruthenium metal complex on a surface thereof; bonding the glass substrate and the metal plate covered with platinum with the frame being between the glass substrate and metal plate; injecting into space (housing) thus formed an electrolyte containing iodine through a pin hole formed in the glass substrate. This is disclosed in Japanese Patent Application Kokai (Laid-Open) No. 2007-287593 (paragraphs 0029 to 0035 and FIG. 1).

In recent years, a dye-sensitized solar cell having a dye-layered-structure has been put under consideration for further improvement of efficiency. This solar cell has two or more layers of sensitizing dye that absorb light of different wavelength regions, thereby broadening its absorption wavelength region. See “Proposal for High Efficiency Dye-Sensitized Solar Cell Structure,” by Shuji Hayase and three others; Technical Digest of the International PVSEC-17, 2007, pp. 81-82.

### SUMMARY OF THE INVENTION

As discussed above, improvement in photoelectric conversion efficiency of a dye-sensitized solar cell is indispensable for the widespread use of solar cells. For that sake, an absorption amount of sensitizing dye needs to be increased. However, since the amount of sensitizing dye absorbed into a porous layer per unit volume is fixed, it becomes necessary to thicken the porous layer to increase the absorption amount of sensitizing dye.

For example, when forming a porous layer having a thickness of 20 μm (micrometer) while considering a diffusion length of an excited electron (about 10 μm), it is impossible in theory to fully catch excited electrons unless a thickness of a collector electrode is about 10 μm.

One approach for forming a collector electrode with such a structure includes the step of forming a tungsten film having a thickness of about 10 μm and the step of patterning the tungsten film by photolitho etching. However, when the tungsten film is thick, it is difficult to form a vertical end face after the etching.

Furthermore, when the tungsten film has a thickness of 3 μm or more, warpage or bending occurs in a glass substrate due to a difference in thermal expansion coefficients between the tungsten film and the glass substrate. If it occurs, the bending in the glass substrate causes defects in the patterning step during the collector electrode fabricating process.

The same problem occurs in a solar cell that has a dye-layered structure (i.e., a plurality of layers of sensitizing dyes). This solar cell is the dye-sensitized solar cell described in the earlier-mentioned “Proposal for High Efficiency Dye-Sensitized Solar Cell Structure,” by Shuzi Hayase and three others; Technical Digest of the International PVSEC-17, 2007. If the photoelectric conversion efficiency should be improved, this problem needs to be solved. The present invention deals with this problem.

An object of the present invention is to provide a method for easily forming a dye-sensitized solar cell having a thick porous layer without increasing a thickness of a collector electrode.

Another object of the present invention is to provide a dye-sensitized solar cell that can have a thick porous layer without increasing a thickness of a collector electrode.

According to one aspect of the present invention, there is provided a dye-sensitized solar cell that includes a light transmissive substrate and a partition wall provided on the substrate. A plurality of recesses are defined on the substrate by the partition wall. Each recess has an opening partitioned by the partition wall. The solar cell also includes a collector electrode that covers (extends over) the partition wall. The collector electrode has an end face on a bottom surface of each recess. The solar cell also includes a porous layer that covers the light transmissive substrate within each recess and also covers the collector electrode. The porous layer has at least one kind of sensitizing dye absorbed therein.

The porous layer is partly embedded within the recesses in order to increase the thickness of the porous layer. Even if the collector electrode of the solar cell is thin, excited electrons ejected from the porous layer are easily drawn into the collector electrode extending along the side surface of the partition wall. Thus, the thickness of the porous layer as a whole is substantially increased, and an amount of sensitizing dye absorbed in the porous layer is increased. Accordingly, a dye-sensitized solar cell having an improved photoelectric conversion efficiency and having a thick porous layer can be easily obtained without increasing the thickness of the collector electrode.

The collector electrode may have a window that penetrates the collector electrode and reaches a top of the partition wall. Two or more kinds of sensitizing dyes may be absorbed in the porous layer. The sensitizing dyes may include Ru. Each recess may have a depth of between 5 micrometer and 20 micrometer. Each recess may have a shape of inverted truncated-hexagonal pyramid. The opening of each recess may have a hexagonal shape. The substrate may be a glass substrate. The porous layer may be an anode electrode of the solar cell. The porous layer may have a nano-size porous structure. The porous layer may have a thickness of between 5 micrometer and 10 micrometer, when measured from the top of the partition wall. The solar cell may include a counter electrode (cathode electrode). The counter electrode may include a metal plate and a catalyst layer. The solar cell may also include an electrolyte. The collector electrode may have a thickness of 3 micrometer or less. The solar cell may further include a protective element provided at an end face of the collector electrode.

According to another aspect of the present invention, there is provided a method of fabricating a dye-sensitized solar cell. The method includes preparing a light transmissive substrate, and forming a plurality of recesses on (in) the substrate by a partition wall such that each recess has an opening partitioned by the partition wall. The method also includes forming a metal layer on the light transmissive substrate such that the metal layer covers the partition wall and the recesses. The method also includes etching the metal layer within each recess to expose the light transmissive substrate in each recess, thereby forming a collector electrode that covers the partition wall and has an end face on the bottom surface of each recess. The method also includes applying a paste containing fine particles of a metallic oxide over the light transmissive substrate and sintering the paste to form a porous layer that covers the light transmissive substrate within each recess and collector electrode. The method also includes making the porous layer absorb at least one kind of sensitizing dye.

The method may further include forming a window that penetrates the metal layer and reaches a top of the partition wall. A plurality of sensitizing dyes may be absorbed in the porous layer. The substrate may be a glass substrate. The sintering may be performed at a temperature of about 450 degrees C. The method may also include washing the substrate with ethanol. The method may also include connecting a counter electrode and a frame to the substrate. The method may also include introducing an electrolyte between the frame and the substrate.

These and other objects, aspects and advantages of the present invention will become apparent to those skilled in the art when the following detailed description is read and understood in conjunction with the appended claims and drawings.

### BRIEF DESCRIPTION OF THE DRAWINGS

FIG. 1 illustrates a cross-sectional view of a dye-sensitized solar cell of Embodiment 1.

FIG. 2 is an enlarged top view of the part II in FIG. 1.

FIG. 3 is a cross-sectional view taken along the line III-III in FIG. 2.

FIG. 4A to 4E are a series of diagrams showing a method of fabricating the dye-sensitized solar cell of Embodiment 1.

FIG. 5 shows an enlarged top view of a glass substrate shown in FIG. 4A.

FIG. 6 shows an enlarged top view of a first structure of Embodiment 2.

FIG. 7 is a cross-sectional view taken along the line VII-VII in FIG. 6.

FIGS. 8A to 8D and 9A to 9B are a series of illustrations that show a method of fabricating the dye-sensitized solar cell of Embodiment 2.

### DETAILED DESCRIPTION OF THE INVENTION

Exemplary embodiments of a dye-sensitized solar cell and methods of fabricating the dye-sensitized solar cell of the present invention will be described with reference to the drawings.

### Embodiment 1

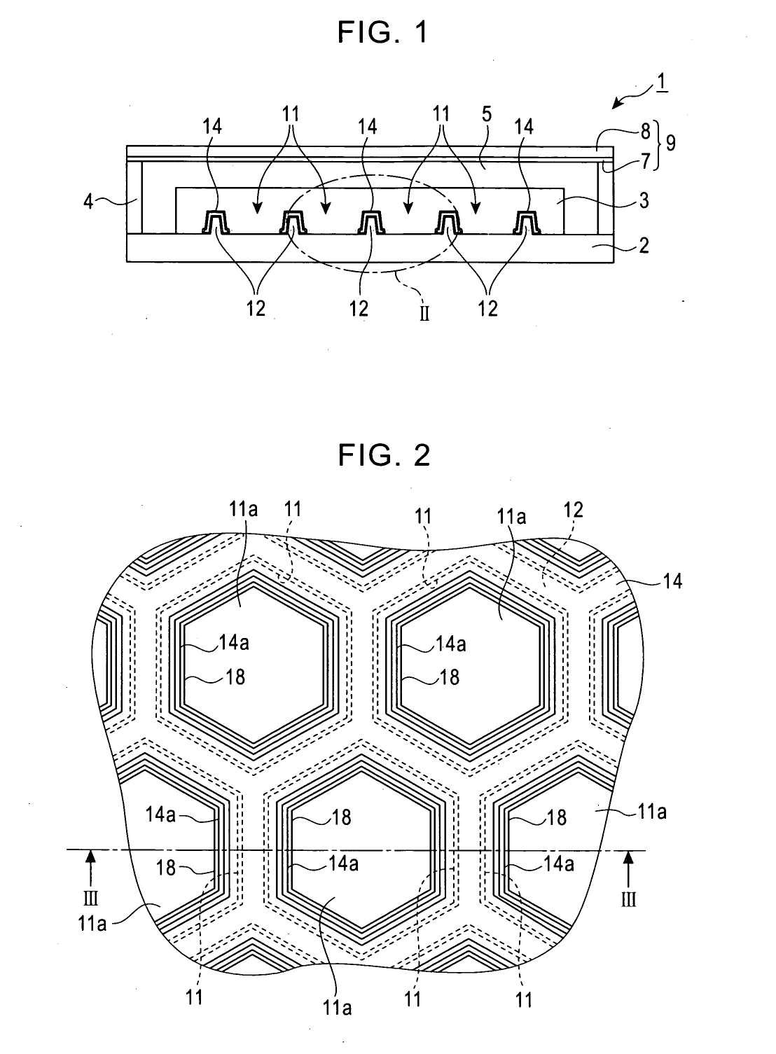

Referring to FIG. 1 to FIG. 5, a dye-sensitized solar cell of the first embodiment will be described. It should be noted that a porous layer is omitted in FIG. 2.

In FIG. 1, a dye-sensitized solar cell 1 includes a glass substrate 2, a porous layer 3 (anode electrode), a counter electrode 9 (cathode electrode) and an electrolyte 5. The porous layer 3 is formed in a central part of an upper surface of the glass substrate 2. The glass substrate 2 functions as a light transmissive substrate. The glass substrate 2 has insulation properties and light transmission properties. The light transmission properties mean properties of capable of transmitting light. The glass substrate 2 is transparent or semi-transparent. The counter electrode 9 includes a metal plate 8 that has a coating of catalyst layer 7. The metal plate 8 has conductivity. The catalyst layer 7 includes a catalyst, such as platinum (Pt), that promotes a reduction reaction of the electrolyte 5. The counter electrode 9 is joined to the glass substrate 2 with a frame 4. The frame 4 stands between the counter electrode 9 and the glass substrate 2. The electrolyte 5 includes iodine (I) confined within space defined by the substrate 2, the frame 4, the porous layer 3 and the catalyst layer 7 of the counter electrode 9.

The porous layer 3 is a semiconductor layer having a nanoporous structure. The porous layer 3 is formed from a paste that has been subjected to sintering. The paste contains fine particles of metallic oxides such as titanium oxide (TiO₂). For example, titanium oxide pastes such as Ti-Nanoxide D/SP available from Solaronix, Inc. can be employed. The porous layer 3 has sensitizing dye, such as a ruthenium (Ru) metal complex, that is absorbed in a surface of the porous structure.

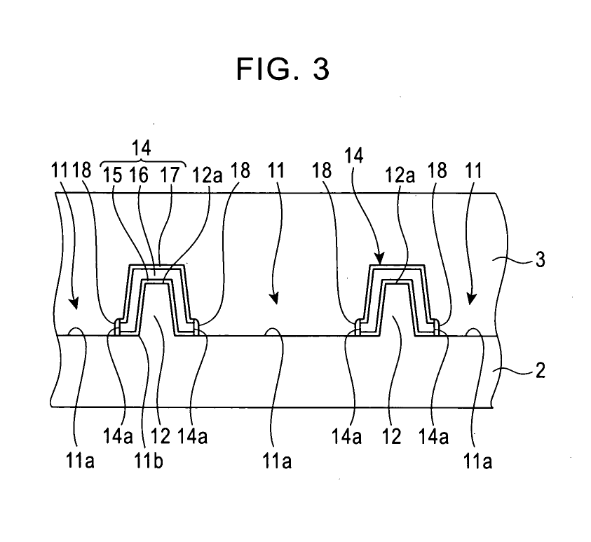

In FIGS. 2 and 3, a plurality of recesses 11 formed on the glass substrate 2 will be described. Each recess 11 has: a shape of an inverted truncated hexagonal pyramid. Each recess 11 has a regular hexagon-shaped opening. Each recess 11 also has a bottom. The recesses 11 are equally spaced form one another and partitioned by a partition wall 12.

A collector electrode 14 is formed by layering a close contact layer 15, a metal layer 16 and a cap layer 17. The close contact layer 15 is made of titanium nitride (TiN). The metal layer 16 is made of conductive materials such as tungsten (W) and iridium (Ir). The cap layer 17 is made of a material such as titanium nitride and titanium nitride alloy (Ti—Al—N). The cap layer 17 protects the metal layer 16 from oxidation and corrosion by the electrolyte 5. The collector electrode 14 covers (extends over) a top surface 12a and a side surface of the partition wall 12. The top surface 12a of the partition wall 12 define an upper surface of the glass substrate 2. The collector electrode 14 also extends over a bottom surface 11a of the recess 11. On the bottom surface 11a of the recess 11, the collector electrode 14 has an end face 14a that exposes the glass substrate 2 in a shape of a regular hexagon.

A side wall element 18 is provided on each end face 14a of the collector electrode 14. The end face 14a is present on the bottom surface 11a of the recess 11. The side wall element 18 is formed for a purpose similar to that of the cap layer 17. The side wall element 18 is made of a material similar to that of the cap layer 17.

To secure a light-receiving area that receives the sunlight from a lower face of the glass substrate 2, it is desirable that a side surface of the recess 11 formed in the glass substrate 2 (i.e., a side surface of the partition wall 12 that defines (surrounds) the recess 11) stand vertically on the upper surface of the glass substrate 2. However, when forming the side wall element 18, a material such as titanium nitride tends to remains on the cap layer 17 and therefore the cap layer 17 becomes (looks) thick if the recess 11 has the vertical side surface. In order to prevent this, it is preferred that the side surface of the recess 11 has a slope (i.e., an inclined surface, not the vertical surface) from the top surface 12a of the partition groove 12 to the bottom surface 11a of the recess 11. The recess 11 of the illustrated embodiment is therefore formed in a shape of an inverted truncated hexagonal pyramid.

An extending portion of the collector electrode 14 lying on the bottom surface 11a of the recess 11 has a length as short as possible from a corner 11b of the side surface and the bottom surface 11a of the recess 11 in order to secure a light-receiving area (to have a sufficient light-receiving area).

A depth of the recess 11 is between 5 μm and 20 μm in this embodiment (between 50% and 200% of a diffusion length of an excited electron). The diffusion length of the excited electron is about 10 μm in this embodiment. This depth of the recess 11 is decided to increase a thickness of the porous layer 3 and improve the photoelectric conversion efficiency.

It should be noted that the depth of the recess 11 is arbitrarily set within the above-mentioned range depending on a photoelectric conversion efficiency required of the dye-sensitized solar cell 1.

The porous layer 3 covers the glass substrate 2 within the recess 11 and surfaces of the collector electrode 14 that do not contact the partition wall 12 (the glass substrate 2). A distance between the top surface 12a of the partition wall 12, which is an upper surface of the glass substrate 2, and an upper surface of the porous layer 3, i.e., a film thickness of the porous layer 3 measured from the top level of the glass substrate 2 is between 50% and 100% of the diffusion length of the excited electron (between 5 μm and 10 μm in the illustrated embodiment).

A diameter of a circle circumscribing the regular hexagon that defines the opening of the recess 11 is about 150% of the diffusion length of the excited electron (about 15 μm in this embodiment) so that all excited electrons ejected from the porous layer 3 embedded within the recess 11 and the porous layer 3 formed on the glass substrate 2 may be drawn into the collector electrode 14 formed on the circumference surface of the recess 11 and the collector electrode 14 formed on the partition wall 12.

In this embodiment, the structure of the solar cell shown in FIG. 3, i.e., a structure including the glass substrate 2, the collector electrode 14 having the side wall element 18 on the end face 14a formed on the bottom surface 11a of the recess 11, and the porous layer 3 that fills the recess 11 and also covers the collector electrode 14 is called a first structure, and the remaining structure, i.e., a structure including the counter electrode 9 having the catalyst layer 7 and the frame 4 (FIG. 1) is called a second structure.

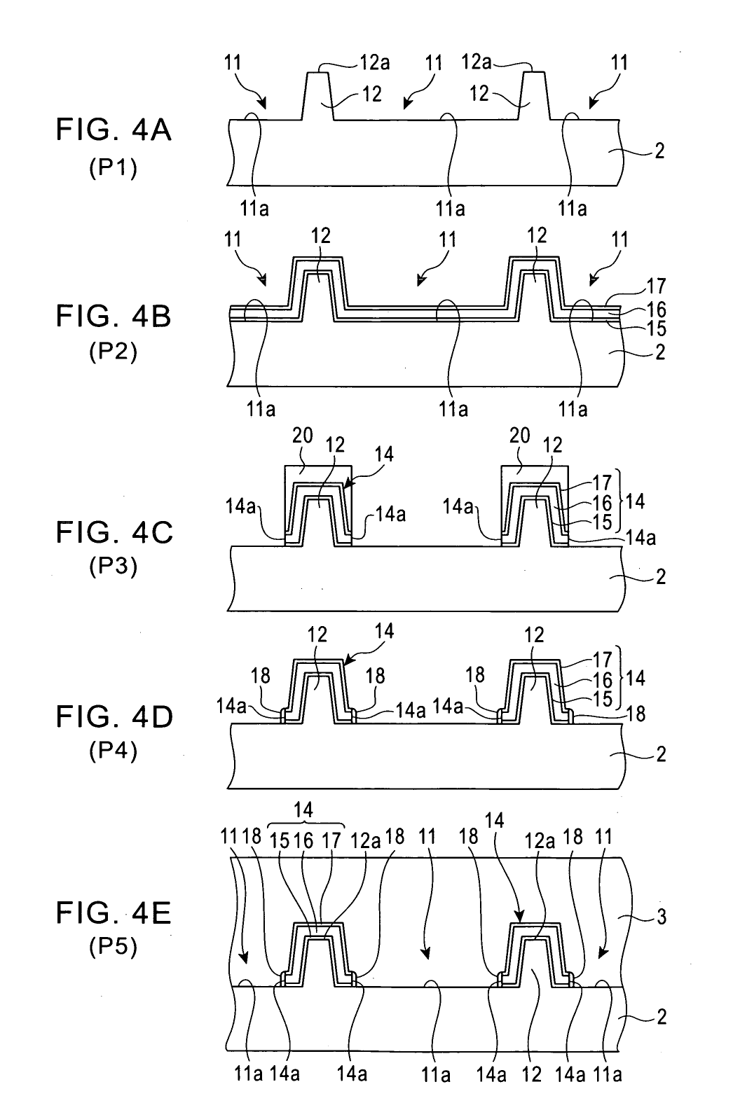

Referring to FIG. 4C, a resist mask 20 is formed by applying a positive or negative photoresist over the upper surface of the glass substrate 2, exposing the applied photoresist by photolithography, and performing development processing on the exposed photoresist. This mask member 20 is used as a mask in the etching step in this embodiment.

In the dye-sensitized solar cell 1 having the above-described structure, the porous layer 3 formed in a central part of the glass substrate 2 and having sensitizing dye absorbed therein functions as an anode electrode (negative electrode) of the dye-sensitized solar cell 1 and the counter electrode 9 having the catalyst layer 7 functions as a cathode electrode (positive electrode) of the dye-sensitized solar cell 1.

When an external load is connected between these electrodes 3 and 9 by external wiring (not shown) and sunlight enters the solar cell 1 from the glass substrate 2 side, the sensitizing dye absorbed in a surface of the porous structure of the porous layer 3 absorbs the light in a particular wavelength range, is excited by the light, and ejects electrons.

Upon ejection, the excited electrons flow into the collector electrode 14 that exists within a diffusion length range of the electrons. The external load connected by the external wiring is driven by the electrons. Then, the electrons flow into the counter electrode 9. The electrons go through iodine in the electrolyte 5, and are received by the sensitizing dye which has become a cation after ejecting electrons. The sensitizing dye thus returns to the original condition.

According to this cycle, the dye-sensitized solar cell 1 functions as a solar cell that supplies current to the external load.

A method of fabricating the above-described dye-sensitized solar cell will be described with reference to steps P1 to P5 shown in FIGS. 4A to 4E, respectively.

First, a step P1 of fabricating the first structure will be described (FIG. 4A).

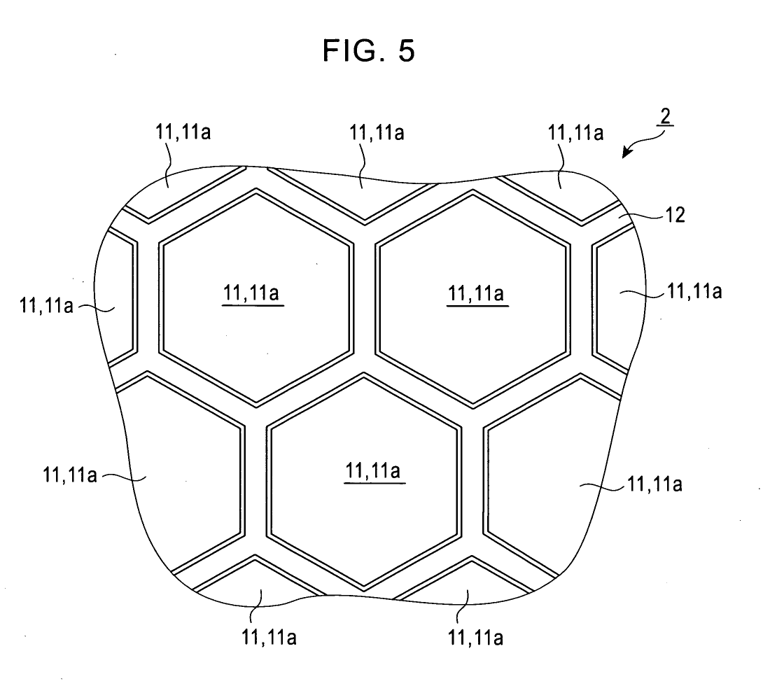

The glass substrate 2 is prepared. On the upper surface of the glass substrate 2, a resist mask (not shown in the figure, but it is similar to the resist mask 20 in FIG. 4C) is formed by lithography. By the resist mask, an area of the glass substrate 2 where the recess 11 is to be formed is exposed. In other words, an area where the partition wall 12 is to be formed is covered by the resist mask. Using the resist mask 20 as an etching mask, the exposed glass substrate 2 is etched by anisotropic etching, thereby forming a plurality of recesses 11. As shown in FIG. 5, each of the recesses 11 has a shape of an inverted truncated hexagonal pyramid with a regular hexagon-shaped opening. Each recess 11 has a depth of about 5 to 20 μm (measured from the top surface 12a of the partition wall 12 to the bottom surface 11a of the recess 11). The recesses 11 are partitioned from one another by the partition wall 12. After that, the resist mask is removed.

The next step P2 is shown in FIG. 4B. On the glass substrate 2, which now has the recesses 11, titanium nitride is deposited by sputtering or chemical vapor deposition (CVD) to form the close contact layer 15. The layer 15 has a film thickness of about 10 to 100 nm. A conductive material is deposited on the close contact layer 15 by sputtering or CVD to form the metal layer 16. The metal layer has a film thickness of about 50 to 1000 nm. On the metal layer 16, a material such as titanium nitride is deposited by sputtering or CVD to form the cap layer 17. The cap layer 17 has a film thickness of about 10 to 100 nm.

The third step P3 is shown in FIG. 4C. The resist mask 20 is formed on the cap layer 17 by photolithography. During the photolithography, an exposure beam is focused progressively (step-by-step) in the depth direction of the recess 11. The resist mask 20 covers an area where the collector electrode 14 is to be formed. Using the resist mask 20 as an etching mask, the cap layer 17, the metal layer 16 and the close contact layer 15 are etched by anisotropic etching to expose the glass substrate 2 in the bottom surface 11a of each recess 11. Accordingly, the collector electrode 14 that covers the partition wall 12 is formed.

In this manner, the collector electrode 14 having a normal thickness (height) is formed.

The fourth step P4 is shown in FIG. 4D. The resist mask 20 formed in the step P3 is removed. Titanium nitride or another suitable material is deposited by sputtering or CVD up to a thickness of about 10 to 100 nm on the bottom surface 11a of each recess 11, the upper surface of the collector electrode 14, and each end face 14a on the bottom surface 11a. Then, the deposited layer of titanium nitride is etched by anisotropic etching to expose the bottom surface 11a of each recess 11 and the upper surface of the collector electrode 14. On each end face 14a of the collector electrode 14 on the bottom surface 11a of the recess 11, the side wall element 18 is formed.

In this manner, the cap layer 17 and the side wall element 18, which are made of a material such as titanium nitride, are formed over the entire surface of the collector electrode 14. As a result, oxidation resistance and corrosion resistance of the collector electrode 14 against the electrolyte 5 is improved.

The last step P5 is shown in FIG. 4E. By a screen printing method, the upper surface of the glass substrate 2 is coated with titanium oxide paste so as to fill the interior of the recess 11 with the paste and to form a titanium oxide paste layer that covers the collector electrode 14. This titanium oxide paste is sintered at a temperature about 450° C.

By this sintering processing, a solvent in the titanium oxide paste layer is evaporated, and fine particles of titanium oxide are physically and electrically bonded to one another to form a porous structure 3. Accordingly, the porous layer 3 is obtained. The thickness of the porous layer 3, measured from the top level of the glass substrate 2 is about 5 to 10 μm.

The glass substrate 2 with the porous layer 3 is then immersed for a predetermined period of time in an alcohol solution that contains sensitizing dye made of ruthenium metal complex to make the sensitizing dye absorbed in a surface of the titanium oxide having the porous structure. After that, the glass substrate 2 with the porous layer 3 is washed with ethanol (CH₃CH₂OH) and dried.

Through the above-described steps P1 to P5, the first structure of the solar cell is formed, which includes on the glass substrate 2 the thick porous layer 3 having the sensitizing dye absorbed therein.

Then, the frame 4 of the second structure is attached (bonded) to a circumference of the glass substrate 2 of the first structure such that the catalyst layer 7 of the second structure faces the porous layer 3 of the first structure face. The second structure is made by fixing the counter electrode 9 to the frame 4. The counter electrode 9 and frame 4 are prepared in separate processes. The electrolyte 5 is injected from an inlet (not shown) provided in the frame 4, and then the inlet is closed by a material such as an epoxy resin. The electrolyte 5 is thus confined within the space defined by the porous layer 3 and the second structure.

In this manner, the dye-sensitized solar cell 1 of the first embodiment shown in FIG. 1 is formed.

As described above, the collector electrode 14 of the solar cell 1 is formed along (over) the side surface of the partition wall 12 that defines (surrounds) each recess 11. Thus, although the collector electrode 14 is thin (3 μm or less in thickness), the porous layer 3 is thick. Accordingly, excited electrons ejected from the porous layer 3 (the porous layer 3 is partly embedded within the recesses 11 formed by digging out the glass substrate 2) can be easily drawn into the collector electrode 14. This can suppress or prevent the occurrence of defects in patterning due to the bending in the glass substrate 2 caused by the metal layer 16 of the collector electrode 14. This also increases an amount of sensitizing dye to be absorbed into the porous layer 3 because the substantial thickness of the porous layer 3 becomes about 1.5 to 3 times the thickness of a conventional porous layer. Thus, by increasing the thickness of the porous layer 3 without increasing the thickness of the collector electrode 14, a dye-sensitized solar cell 1 with improved photoelectric conversion efficiency can be easily obtained.

Since the end face 14a of the collector electrode 14 having a thickness of 3 μm or less is located on the glass substrate 2 which is the bottom surface 11a of the recess 11, the end face 14a can easily have a vertical face without impairing etching workability (proccessability) of the thin end face 14a. Thus, the side wall element 18, which is provided for the purpose of improving oxidation resistance and corrosion resistance to the electrolyte 5 of the metal layer 16, can be easily formed on the end face 14a of the collector electrode 14.

Furthermore, in the first embodiment, the depth of the recess 11, on the circumferential side surface of which the collector electrode 14 is formed, is in the range of between 50% and 200% of the diffusion length. of the excited electron. The diameter of the circle circumscribing the regular hexagonal opening of the recess 11 is about 150% of the diffusion length of the excited electron. The film thickness of the porous layer 3 on the glass substrate 2 is in the range of between 50% and 100% of the diffusion length of the excited electron. The collector electrode 14 thus extends within the diffusion length of the excited electron. Therefore, all the excited electrons ejected from the sensitizing dye upon the application (radiation) of sunlight are introduced into the collector electrodes 14.

As explained above, in the illustrated embodiment, a plurality of recesses 11 each having the regular hexagonal opening partitioned by the partition wall 12 are formed on the glass substrate 2 of the dye-sensitized solar cell 1. The collector electrode 14 that covers the partition wall 12 and has the end face on the bottom surface of each recess 11 is provided. The porous layer 3 that has sensitizing dye absorbed therein and covers the glass substrate 2 in the bottom face of each recess 11 and the collector electrode 14 is provided on the glass substrate 2 within each recess 11 and on the collector electrode 14. Therefore, if the collector electrode 14 is as thin as an ordinary collector electrode, excited electrons ejected from the porous layer 3 that is partly embedded within the recesses 11 in order to increase the thickness of the porous layer 3 can be easily flow into the collector electrode 14 formed along the side surface of the partition wall 12 that defines the circumference of the recess 11. Because the thickness of the porous layer 3 is substantially increased as a whole, and an amount of the sensitizing dye absorbed in the porous layer 3 is increased, a dye-sensitized solar cell having improved photoelectric conversion efficiency can be easily formed without increasing the thickness of the collector electrode 14.

### Embodiment 2

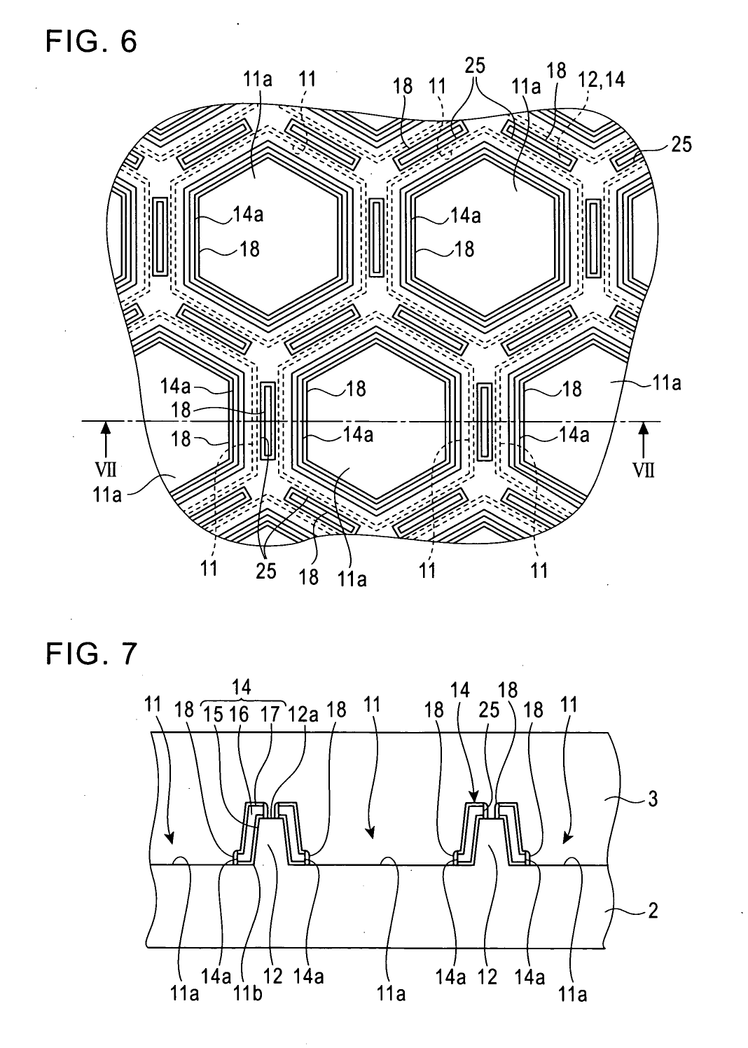

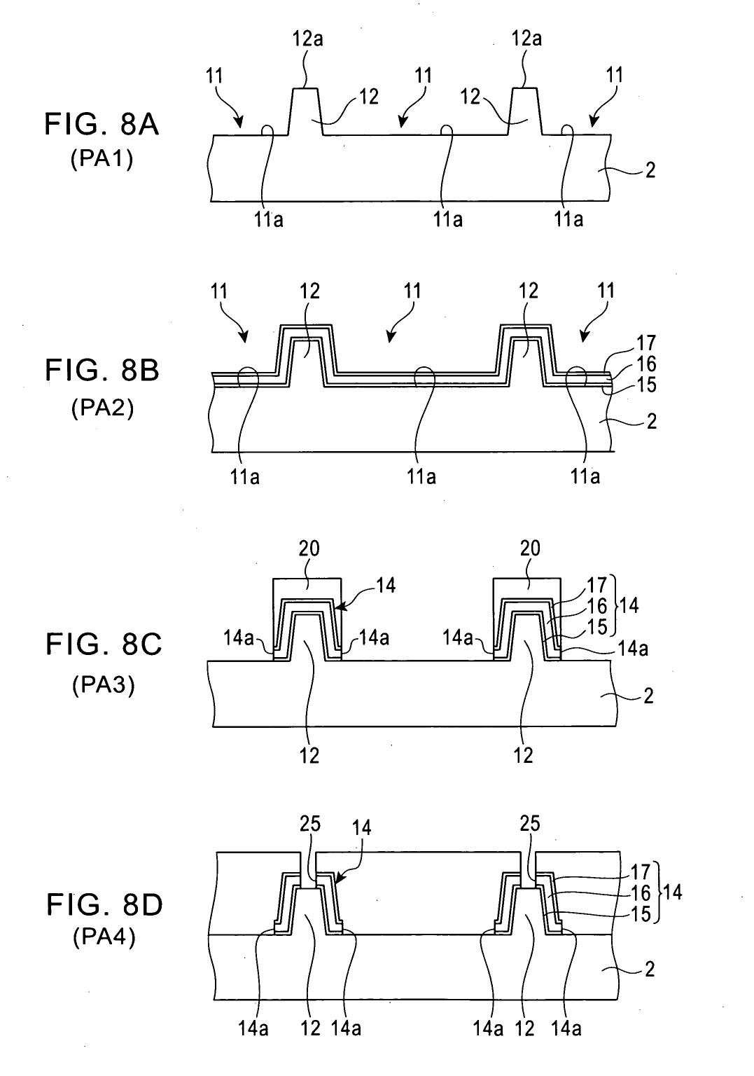

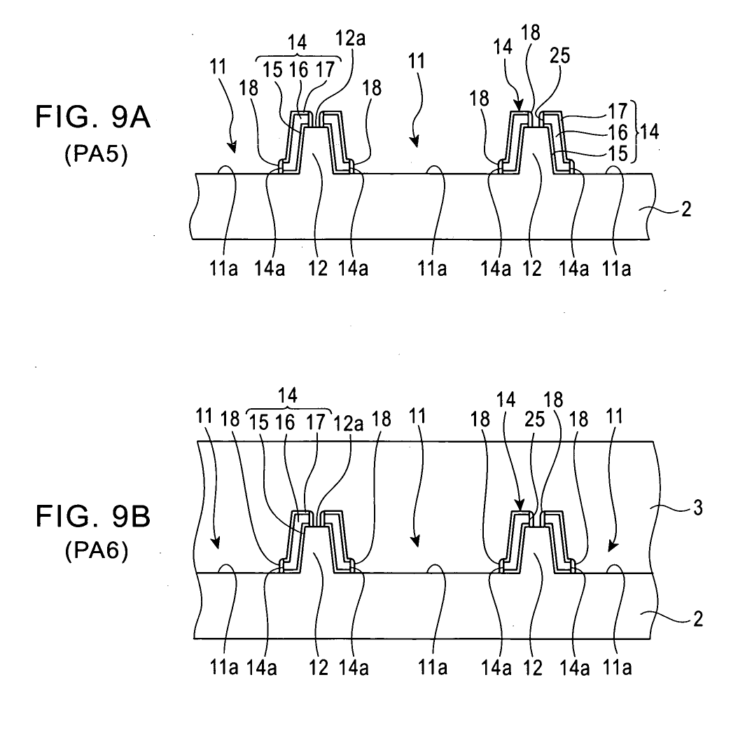

Referring to FIG. 6 to FIG. 9B, a solar cell according to Embodiment 2 will be described. FIG. 6 illustrates an upper surface of the first structure of the solar cell of Embodiment 2. FIG. 8A to 8D and FIG. 9A to 9B illustrates in combination a solar cell manufacturing method.

FIG. 6 is similar to FIG. 2 (Embodiment 1) and depicts an enlarged view of an upper surface of a solar cell. The porous layer is omitted from the drawing.

It should be noted that elements and parts similar to those of Embodiment 1 are designated by the same reference numerals and symbols and explanations therefor are omitted.

As shown in FIGS. 6 and 7, a window 25 is formed in a central part of the collector electrode 14. The collector electrode 14 extends over (covers) the top surface 12a of the partition wall 12. The window 25 is located between adjacent recesses 11. The window 25 is a through hole that penetrates the collector electrode 14 and reaches the top face 12a of the partition wall 12. The horizontal cross-sectional shape of the window 25 is a rectangle. Thus, the window 25 defines a rectangular opening. The window 25 is provided to increase the light-receiving area of the dye-sensitized solar cell 1, as understood from the comparison of Embodiment 2 with Embodiment 1.

On the side walls of the window 25, which are newly formed upper end faces of the collector electrode 14, a side wall element 18 made of a material similar to that of the cap layer 17 is formed for a purpose similar to that of the cap layer 17.

In this embodiment, a structure shown in FIG. 7 is called a first structure. The constitution of the second structure is the same as that in Embodiment 1.

A method of fabricating a dye-sensitized solar cell 1 of the second embodiment will be described with reference to steps PA1 to PA6 shown in FIGS. 8A to 8D and 9A to 9B, respectively.

First, the process of fabricating the first structure will be described.

Processing in the steps PA1 (FIG. 8A) to PA3 (FIG. 8C) of Embodiment 2 is the same as that performed in the steps P1 (FIG. 4A) to P3 (FIG. 4C) of Embodiment 1. Thus, explanations of the steps PA1 to PA3 are omitted.

In the step PA4 (FIG. 8D), the resist mask 20 formed in the step PA3 is removed. On the cap layer 17 of the collector electrode 14 that covers the top surface 12a of the partition wall 12, a resist mask 20 is again formed by photolithography such that a predetermined area of the cap layer 17 where the window 25 is to be formed is exposed. Using the resist mask 20 as an etching mask, the cap layer 17, the metal layer 16 and the close contact layer 15 are etched by anisotropic etching, and the glass substrate 2 at the top surface 12a of the partition wall 12 is exposed. The window 25 is thus formed in the collector electrode 14 on the top surface 12a of the partition wall 12 such that the window 25 penetrates the collector electrode 14 and reaches the top surface 12a of the partition wall 12.

In this manner, a collector electrode 14 having a normal thickness (height) is formed.

The subsequent step PA5 is shown in FIG. 9A. The resist mask 20 formed in the step PA4 is removed. A material such as titanium nitride is deposited up to the thickness of about 10 to 100 nm by sputtering or CVD. This material is deposited over the bottom surface 11a of the recess 11, the side (inner) walls of the window 25, the top 12a of the partition wall 12, the upper surface of the collector electrode 14, and the end face 14a of the collector electrode 14 on the bottom surface 11a of the recess 11. The deposited layer of this material such as titanium nitride is etched by anisotropic etching, thereby exposing the bottom surface 11a of the recess 11, the top surface 12a of the partition wall 12 within the window 25 and the upper surface of the collector electrode 14. The side wall element 18 is then formed on the end face 14a of the collector electrode 14 and on the side surfaces of the window 25, which are upper end faces of the collector electrode 14.

In this manner, the cap layer 17 and the side wall element 18, which are made of a material such as titanium nitride, are formed on the entire surface of the collector electrode 14, and thus, oxidation resistance and corrosion resistance to the electrolyte 5 of the collector electrode 14 can be improved.

Processing performed in the next step PA6 (FIG. 9B) is the same as that performed in the step P5 (FIG. 4E) of Embodiment 1. Thus, explanation of the step PA6 is omitted here.

Also, processing for joining the second structure to the first structure and sealing the electrolyte 5 in the solar cell 1 are the same as those in Embodiment 1. Thus, explanations thereof are omitted.

As explained above, the second embodiment has, in addition to the constitution of Embodiment 1, the window 25 in the collector electrode 14 on the top surface 12a of the partition wall 12, and therefore, the light-receiving area of the dye-sensitized solar cell 1 is expanded. Thus, photoelectric conversion efficiency of the dye-sensitized solar cell 1 having a thick(er) porous layer 3 is further enhanced.

Since the window 25, which defines the end faces of the collector electrode 14 having a thickness of 3 μm or less, is formed on the glass substrate 2 which is the top surface 12a of the partition wall 12, the window 25 can have vertical side (inner) walls without impairing the etching workability of the end faces of the thin collector electrode 14. Thus, the side wall element 18, which is provided for improving oxidation resistance and corrosion resistance to the electrolyte 5 of the metal layer 16, can be easily formed on the side walls of the window 25.

As explained above, the second embodiment has, in addition to the advantages similar to those of Embodiment 1, additional advantages. For example, the light-receiving area of the dye-sensitized solar cell 1 can be increased by forming, in the collector electrode 14 that covers the top of the partition wall 12, the window 25 that penetrates the collector electrode 14 and reaches the top of the partition wall 12. Therefore, the photoelectric conversion efficiency of a dye-sensitized solar cell having the thick porous layer 3 can be further enhanced.

It should be noted that the cap layer and the side wall element 18 are formed on the collector electrode 14 in the first and second embodiments from the view point of oxidation resistance and corrosion resistance of the metal layer of the collective electrode 14, but the cap layer 17 and side wall element 18 are not indispensable elements of the invention; the cap layer 17 and/or side wall element 18 may be formed when necessary or appropriate.

Although one kind of sensitizing dye is absorbed in the porous layer 3 in the first and second embodiments, two or more kinds of sensitizing dyes that can absorb light in different wavelength regions may be absorbed in the porous layer 3. Given such constitution, a plurality of kinds of sensitizing dyes absorbed in the porous layer 3 can respectively eject excited electrons upon excitation by light of a plurality of wavelength regions. Thus, the photoelectric conversion efficiency of the thick porous layer 3 can be further enhanced.

In this case, the two or more kinds of sensitizing dyes may be sequentially layered and absorbed in the porous layer 3, or mixed and absorbed in the porous layer 3.

Although the titanium oxide paste for forming the porous layer 3 of the dye-sensitized solar cell 1 is applied by screen printing in the first and second embodiment, the paste may be applied by coating.

This application is based on Japanese Patent Application No. 2008-184978 filed on Jul. 16, 2008 and the entire disclosure thereof is incorporated herein by reference.

What is claimed is:

1. A dye-sensitized solar cell comprising:
a light transmissive substrate;
a partition wall formed on said light transmissive substrate to define a plurality of recesses on said light transmissive substrate, each said recess having an opening partitioned by the partition wall;
a collector electrode that covers said partition wall and has end faces on a bottom surface of each said recess; and
a porous layer that covers said light transmissive substrate within each said recess and also covers said collector electrode, with at least one kind of sensitizing dye being absorbed in said porous layer.

2. The dye-sensitized solar cell according to claim 1, wherein said collector electrode has a window that penetrates said collector electrode and reaches a top of said partition wall.

3. The dye-sensitized solar cell according to claim 1, wherein said at least one kind of sensitizing dye are a plurality of kinds of sensitizing dyes.

4. The dye-sensitized solar cell according to claim 1, wherein the at least one kind of sensitizing dyes includes Ru.

5. The dye-sensitized solar cell according to claim 1, wherein each said recess has a depth of between 5 micrometer and 20 micrometer.

6. The dye-sensitized solar cell according to claim 1, wherein each said recess has a shape of inverted truncated hexagonal pyramid.

7. The dye-sensitized solar cell according to claim 1, wherein the porous layer serves as an anode electrode of the solar cell.

8. The dye-sensitized solar cell according to claim 1, wherein the porous layer has a nano-size porous structure.

9. The dye-sensitized solar cell according to claim 1, wherein the porous layer has a thickness of between 5 micrometer and 10 micrometer, when measured from the top of the partition wall.

10. The dye-sensitized solar cell according to claim 7 further comprising a cathode electrode.

11. The dye-sensitized solar cell according to claim 10, wherein the cathode electrode includes a metal plate and a catalyst layer.

12. The dye-sensitized solar cell according to claim 1, wherein the collector electrode has a thickness of 3 micrometer or less.

13. The dye-sensitized solar cell according to claim 1 further comprising a protective element provided at an end face of the collector electrode.

14. A method of fabricating a dye-sensitized solar cell of claim 1, comprising the steps of:
providing a light transmissive substrate;
forming a plurality of recesses on the light transmissive substrate by a partition wall such that each of said plurality of recesses has an opening partitioned by said partition wall;
forming a metal layer on said light transmissive substrate such that the metal layer covers said partition wall and said plurality of recesses;
etching said metal layer within each said recess to expose said light transmissive substrate in each said recess, thereby forming a collector electrode that covers said partition wall and has an end face on said bottom surface of each said recess;
applying a paste containing fine particles of a metallic oxide over said light transmissive substrate and sintering said paste to form a porous layer that covers said light transmissive substrate within each said recess and said collector electrode; and
making said porous layer absorb at least one kind of sensitizing dye.

15. The method according to claim 14 further comprising the step of forming a window that penetrates said metal layer and reaches a top of said partition wall.

16. The method according to claim 14, wherein said at least one kind of sensitizing dye includes two or more kinds of sensitizing dye.

17. The method according to claim 14, wherein the sintering is performed at a temperature of about 450 degrees C.

18. The method according to claim 14 further comprising the step of washing the substrate with ethanol after said sintering.

19. The method according to claim 14 further comprising the step of connecting a counter electrode and a frame to the substrate.

20. The method according to claim 19 further comprising the step of introducing an electrolyte between the frame and the substrate.
